(19) United States
(12) Patent Application Publication
(10) Pub. No.: US 2026/0181788 A1
(43) Pub. Date: Jun. 25, 2026

(54) VEHICULAR CAMERA ASSEMBLY WITH PCB ADHERED TO LENS HOLDER

(71) Applicant: Magna Electronics Inc., Auburn Hills, MI (US)

(72) Inventors: Martin Laufer, Ühlingen-Birkendorf (DE); Achim Newiger, Aschaffenburg (DE); Andreas Weis, Gedern (DE); Marc-Andrè Sigle, Alzenau (DE)

(21) Appl. No.: 19/424,360

(22) Filed: Dec. 18, 2025

Related U.S. Application Data
(60) Provisional application No. 63/737,921, filed on Dec. 23, 2024.
(60) Provisional application No. 63/745,834, filed on Jan. 16, 2025.

(51) Int. Cl. H05K 3/303; H04N 23/54

(52) U.S. Cl. CPC H05K 3/305; H04N 23/54

(57) ABSTRACT

A vehicular camera assembly includes a lens barrel accommodating a lens and a camera housing. An imager printed circuit board (imager PCB) includes an imager at a first side. The imager PCB is disposed at the camera housing with the imager facing the lens. An adhesive is disposed between and engages the first side of the imager PCB and the housing. During assembly of the camera, a nozzle dispenses the adhesive onto an attaching portion of the imager PCB and the housing is moved into engagement with the adhesive. As the nozzle dispenses the adhesive, the attaching portion is electrically charged and the nozzle is electrically charged to electrically charge the adhesive. Either the attaching portion is negatively charged and the adhesive is positively charged or the attaching portion is positively charged and the adhesive is negatively charged.

### CROSS REFERENCE TO RELATED APPLICATIONS

The present application claims the filing benefits of U.S. provisional application Ser. No. 63/745,834, filed Jan. 16, 2025, and U.S. provisional application Ser. No. 63/737,921, filed Dec. 23, 2024, which are hereby incorporated herein by reference in their entireties.

### FIELD OF THE INVENTION

The present invention relates generally to a vehicle vision system for a vehicle and, more particularly, to a vehicle vision system that utilizes one or more cameras at a vehicle.

### BACKGROUND OF THE INVENTION

Use of imaging sensors in vehicle imaging systems is common and known. Examples of such known systems are described in U.S. Pat. Nos. 5,949,331; 5,670,935 and/or 5,550,677, which are hereby incorporated herein by reference in their entireties.

### SUMMARY OF THE INVENTION

A driving assistance system or vision system or imaging system for a vehicle utilizes one or more cameras (such as one or more CMOS cameras) to capture image data representative of images exterior of the vehicle. The camera includes a lens holder, and an imager printed circuit board (imager PCB), with the imager PCB fixed to the lens holder, and with a lens barrel (accommodating a lens or lens assembly therein) attached to the lens holder.

A vehicular camera assembly may include a lens barrel accommodating a lens. A camera housing includes a first housing portion and a second housing portion. The lens barrel is disposed at the first housing portion. An imager printed circuit board (imager PCB) includes a first side and a second side opposite the first side and separated from the first side by a thickness of the imager PCB. An imager is disposed at the first side of the imager PCB. The imager PCB is disposed at the camera housing with the imager facing the lens. An adhesive is disposed between and engages the first side of the imager PCB and the first housing portion to adhesively attach the imager PCB at the camera housing. During assembly of the vehicular camera, a nozzle dispenses the adhesive onto an attaching portion of the first side of the imager PCB and, with the adhesive dispensed onto the attaching portion of the first side of the imager PCB the first housing portion is moved into engagement with the adhesive at the first side of the imager PCB. As the nozzle dispenses the adhesive onto the attaching portion of the first side of the imager PCB, the imager PCB is electrically connected to a first voltage source to electrically charge the attaching portion of the first side of the imager PCB and the nozzle is electrically connected to a second voltage source to electrically charge the nozzle and the adhesive. The attaching portion of the first side of the imager PCB may be negatively charged and the nozzle and the adhesive may be positively charged or the attaching portion of the first side of the imager PCB may be positively charged and the nozzle and the adhesive may be negatively charged.

These and other objects, advantages, purposes and features of the present invention will become apparent upon review of the following specification in conjunction with the drawings.

### BRIEF DESCRIPTION OF THE DRAWINGS

FIG. 1 is a plan view of a vehicle with a vision system that incorporates cameras;

FIG. 2 is a perspective view of a camera of the vision system;

FIG. 3 is a schematic view of a process of manufacturing the camera where an imager printed circuit board (PCB) and a nozzle dispensing adhesive onto the imager PCB are electrically charged during dispensing of the adhesive onto the imager PCB;

FIG. 4 is a schematic view of a process of manufacturing the camera where the imager PCB includes a copper surface that is electrically charged and that receives the dispensed adhesive;

FIG. 5 is a sectional view of the imager PCB having a copper layer embedded in a dielectric material with the copper layer electrically connected to a voltage source; and

FIG. 6 is a schematic diagram of a process of manufacturing the camera where portions of the imager PCB configured to receive the adhesive are electrically charged oppositely from the dispensing nozzle and portions of the imager PCB not configured to receive the adhesive.

### DESCRIPTION OF THE PREFERRED EMBODIMENTS

A vehicle vision system and/or driver or driving assist system and/or object detection system and/or alert system operates to capture images exterior of the vehicle and may process the captured image data to display images and to detect objects at or near the vehicle and in the predicted path of the vehicle, such as to assist a driver of the vehicle in maneuvering the vehicle in a rearward direction. The vision system includes an image processor or image processing system that is operable to receive image data from one or more cameras and provide an output to a display device for displaying images representative of the captured image data. Optionally, the vision system may provide display, such as a rearview display or a top down or bird's eye or surround view display or the like.

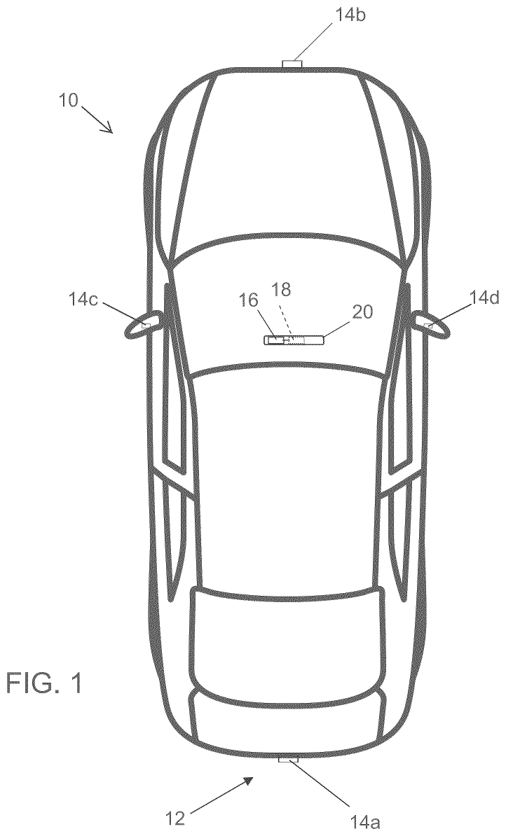

Referring now to the drawings and the illustrative embodiments depicted therein, a vehicle 10 includes an imaging system or vision system 12 that includes at least one exterior viewing imaging sensor or camera, such as a rear backup camera or rearward viewing imaging sensor or camera 14a (and the system may optionally include multiple exterior viewing imaging sensors or cameras, such as a forward viewing camera 14b at the front (or at the windshield) of the vehicle, and a sideward/rearward viewing camera 14c, 14d at respective sides of the vehicle), which captures images exterior of the vehicle, with the camera having a lens for focusing images at or onto an imaging array or imaging plane or imager of the camera (FIG. 1). Optionally, a forward viewing camera may be disposed at the windshield of the vehicle and view through the windshield and forward of the vehicle, such as for a machine vision system (such as for traffic sign recognition, headlamp control, pedestrian detection, collision avoidance, lane marker detection and/or the like). The vision system 12 includes a control or electronic control unit (ECU) 18 having electronic circuitry and associated software, with the electronic circuitry including a data processor or image processor that is operable to process image data captured by the camera or cameras, whereby the ECU may detect or determine presence of objects or the like and/or the system provide displayed images at a display device 16 for viewing by the driver of the vehicle (although shown in FIG. 1 as being part of or incorporated in or at an interior rearview mirror assembly 20 of the vehicle, the control and/or the display device may be disposed elsewhere at or in the vehicle). The data transfer or signal communication from the camera to the ECU may comprise any suitable data or communication link, such as a vehicle network bus or the like of the equipped vehicle.

Typically, active focus and alignment is used to set and secure a focal position of a lens to an imager component, such as an imager printed circuit board (imager PCB) accommodating an imager at a side of the imager PCB. For example, a camera may be assembled using an active PCB alignment, which may use screws to secure the PCB to a lens holder or front camera housing. After the PCB is secured to the lens holder, the lens barrel (such as a threaded lens barrel) is threaded into the lens holder and used to set the focus of the lens relative to the imager. After the lens and imager are optically aligned and focused (via threading the lens barrel into the lens holder), the lens barrel (and lens) is secured to the lens holder with adhesive on the lens threads.

Optionally, active lens alignment may be provided where the imager PCB is secured to the lens holder or front housing using screws and the lens is actively moved to set focus and alignment, whereby a quick cure adhesive is used to set the focus and alignment of the lens relative to the imager. The adhesive acts as a compliant material (before it is cured) to allow for focus and alignment, which is achieved by moving the lens relative to the lens holder. Optionally, the adhesive may be at least partially cured via ultraviolet (UV) light and may further be cured via additional curing. Quick cure adhesives may require UV curing and additional curing.

Optionally, active PCB focus and alignment may be achieved via a one piece lens assembly that is secured to the front housing or lens holder utilizing adhesive initially, and then the imager PCB is actively moved relative to the lens holder to set focus, alignment, and rotation, where a quick cure adhesive is used to set the focus, alignment, and rotation. The adhesive (that bonds the circuit board to the lens holder) acts as a compliant material (before it is cured) to allow for focus and alignment, which is achieved by moving the PCB relative to the lens holder. UV and additional curing may be used to set the focus and alignment of the imager relative to the lens.

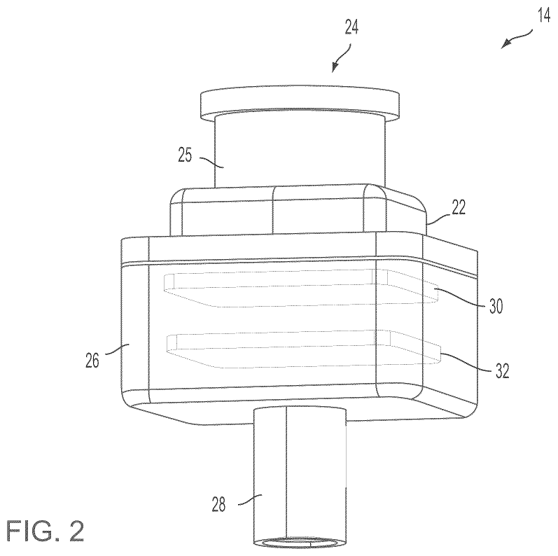

Referring to FIG. 2, the vehicular camera 14 may include a front camera housing or lens holder 22 accommodating a lens assembly 24 (which may include one or more lenses or optic elements disposed along a lens barrel 25), with the lens holder 22 joined or mated to a rear camera housing 26. The rear camera housing 26 may include a connector portion 28 configured to receive an electrical connector for power and data transfer when the camera 14 is disposed at the vehicle 10. An imager PCB 30 accommodating an imager at a first side of the imager PCB 30 is disposed at an interior portion of the camera 14 between the front housing portion 22 and the rear housing portion 26. Optionally, a connector PCB 32 is disposed within the interior portion of the camera 14 and electrically connected between the imager PCB 30 and the connector portion 28.

The imager PCB 30 may be attached to the lens holder 22 during focus and alignment of the lens and imager. For example, a portion of the lens holder 22 may be adhesively attached to the first side of the imager PCB 30 (at which the imager is disposed) and, with the adhesive in an uncured state, the lens holder 22 may be adjusted relative to the imager PCB 30 to focus and align the lens and imager. With the lens and imager aligned and focused, the adhesive may be cured to set the focus and alignment.

The glue joint between the imager PCB and the lens or lens holder may be prone to failure in some situations. For example, the adhesive material may be disposed between a dielectric medium at the imager PCB (e.g., an FR4 dielectric) and a portion of the lens holder (e.g., an aluminum or anodized aluminum portion of the lens holder, a metallic portion of the lens holder or a non-metallic or plastic portion of the lens holder), and the glue joint may fail due to repulsion by charge. As discussed further below, a controlled static charge may be used during a process for manufacturing the camera 14 to overcome this repulsion and prevent or eliminate defective glue joints. Although discussed herein as related to a glue joint between the lens or lens holder 22 and the imager PCB 30, it should be understood that characteristics of the manufacturing process may be suitable for forming other glue joints of the vehicular camera 14, such as between the front camera housing 22 and the rear camera housing 26, between the connector PCB 32 and the rear camera housing 26, and the like.

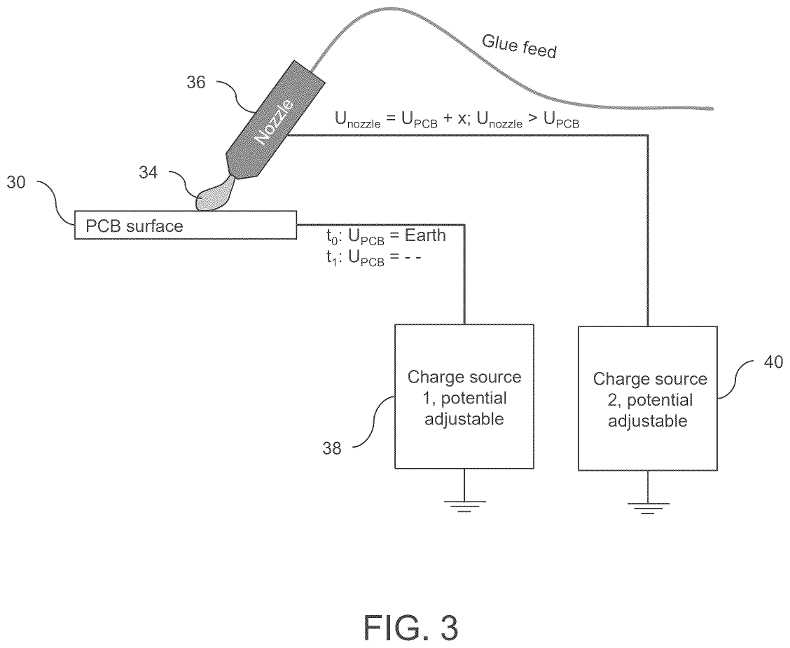

As shown in FIG. 3, during application of adhesive 34 to the first side of the imager PCB 30 (that accommodates the imager and that faces the lens), the adhesive applicator or dispenser or nozzle 36 that delivers or dispenses the adhesive 34 onto the PCB 30 may be electrically charged and/or the imager PCB 30 may be electrically charged so that the charge or potential of the imager PCB 30 is opposite to the charge or potential of the adhesive 34 being dispensed. In the illustrated example, the imager PCB 30 (e.g., a carrier of the PCB with circuitry connected electrically) is connected to a ground or first charge source 38 having a negative charge. Then the potential of the imager PCB 30 is lowered, such as to a charge of −100 volts with a controlled gradient. The sensitivity of the electrical components on the imager PCB 30 is considered as the potential of the imager PCB 30 is lowered equally and the imager PCB 30 is prevented from contacting a material with a different charge. Further, the charge or potential of the adhesive dispenser nozzle 36 is controlled to some positive value greater than the potential of the imager PCB 30 to achieve positive charging of the adhesive 34 being dispensed. For example, the nozzle 36 is electrically conductive and may be electrically connected to a second charge source 40 having a positive charge. With the charge or potential of the nozzle 36 set at a positive value greater than the charge or potential of the imager PCB 30, the charged adhesive 34 is applied to a target area of the imager PCB 30 by moving the nozzle 36 to and at the target location. The charge or potential of the system is kept up or maintained during the whole process.

In some examples, the first charge source 38 may include a negative terminal of a power source and the second charge source 40 may include a positive terminal of the power source, such that the potential at the nozzle 36 is greater than the potential at the PCB 30 and electrical charge or electrical current flows from the nozzle 36 to the PCB 30 via the adhesive 34. This helps with binding of the adhesive 34 at the PCB 30. Optionally, the nozzle 36 and the PCB 30 may be connected to separate or different charge or voltage sources. The nozzle 36 and the PCB 30 may be oppositely charged (i.e., the nozzle 36 may be positively charged and the PCB 30 may be negatively charged) and the PCB 30 may have a greater potential than the nozzle 36 so that electrical charge or electrical current flows from the PCB 30 to the nozzle 36 via the adhesive 34. As discussed further below, intended repulsion can be used to prevent areas from being covered with the glue 34 by charging defined areas with the same potential used on the nozzle 36.

When applying the lens holder or lens to the adhesive 34 at the imager PCB 30, the lens is charged with a potential greater than the charge of the adhesive 34 applied to the imager PCB 30 and the charge or potential of the system is kept up or maintained during the whole process. The lens is moved to its target position while contacting the adhesive 34 and the adhesive 34 is cured to secure the lens relative to the imager.

The application of the charge and the potential difference between the nozzle 36 and the imager PCB 30 may be adapted based on the target surface receiving the adhesive 34 and/or the lens or lens holder 22 engaging the adhesive 34. For example, in FIG. 3, the adhesive 34 is disposed at a dielectric medium or surface of the PCB 30 and thus the dielectric medium may be electrically connected to the ground or charge source 38.

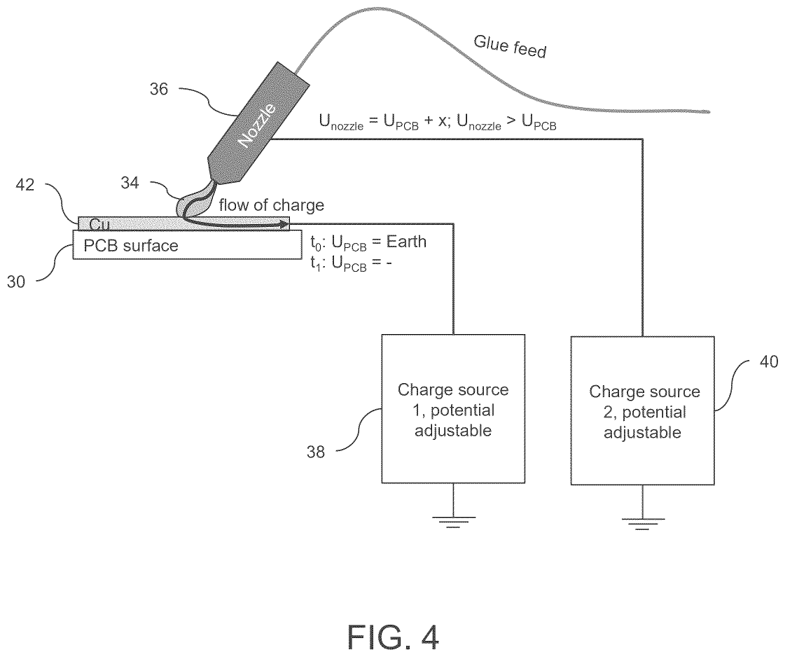

As shown in FIG. 4, the adhesive 34 may be disposed at a conductive portion of the PCB 30, such as a copper surface 42 or other conductive portion of the PCB 30, and the copper surface 42 is electrically connected to the ground or charge source 38. Thus, the flow of charge or current from the adhesive 34 having the greater charge or potential may be from the adhesive 34, through the copper surface 42 to the ground or charge source 38. The PCB 30 may be configured so that semiconductor structures and other structures or components disposed at the PCB 30 and sensitive to electrostatic discharge are out of the path of the flow charge from the target surface to the ground or charge source 38. Provision of charges may be accomplished in any suitable manner, such as by using direct electric connection between the charge sources 38, 40 and conductive portions 42 of the PCB 30 and nozzle 36, or via polarization of non-conductive material at the PCB 30 and/or nozzle 36.

Optionally, areas of different charge on the PCB 30 or lens holder may be formed using other methods. For example, the PCB 30 may be electrically charged and non-attaching portions of the PCB 30 configured not to receive the adhesive 34 may be discharged via exposure of the non-attaching portions to laser light. The remaining charged portions of the PCB 30 (e.g., negatively charged) may be configured to receive the adhesive 34 (e.g., positively charged). In some examples, portions of the PCB 30 may be charged via triboelectric effects or techniques (e.g., electric charge transfer between two objects when they contact or slide against each other), separation, beam / exposure, electrostatic induction (e.g., redistributing an object's electric charge due to the influence of a nearby charged object), and the like.

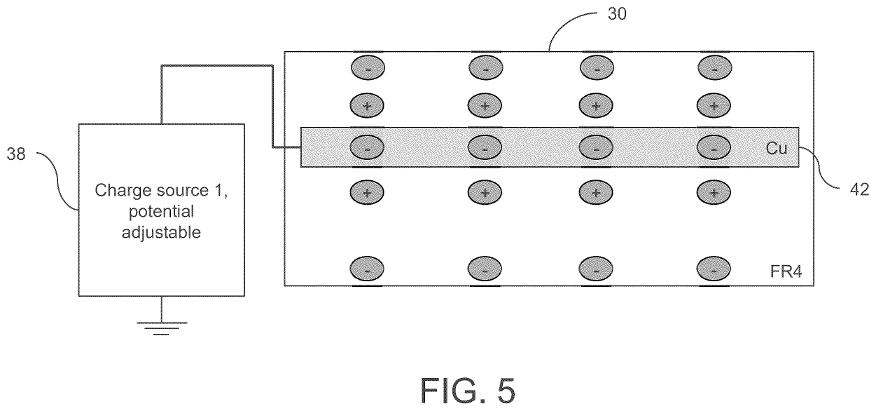

Optionally, the manufacturing process may float the layer below the adhesive 34 with the copper surface 42 connected to the ground or charge source 38 to improve the static attraction using polarization in the dielectric medium (FIG. 5). In other words, the copper surface 42 may be embedded within or beneath the dielectric medium of the PCB 30 at or near the portion of the dielectric medium configured to receive the adhesive 34. Thus, with the copper 42 negatively charged, polarization of the dielectric medium of the PCB 30 may be improved, and the adhesive may be applied to the dielectric medium of the PCB 30 and not contact the conductive portion 42 embedded in the PCB 30.

Optionally, the adhesive 34 may be applied to the copper surface 42 instead of the dielectric medium. For example, a copper contour may be created or formed (e.g., using standard surface finishing) at the imager PCB 30 that generally corresponds to or follows the target contour (i.e., the target location for the adhesive 34 at the PCB 30). This copper contour may be electrically connected to the ground of the PCB 30, or separately electrically connected to the ground or charge source 38 to support application of the adhesive 34 using static charge.

Dispersal of adhesive or other liquids may need to be controlled so that the adhesive 34 does not touch restricted or unwanted portions of the PCB 30. For example, the adhesive 34 may not contact portions of the PCB 30 or other portions of the camera 14 before it is cured. To avoid contact of the adhesive 34 to these portions of the camera 14, the adhesive 34 may be dispensed directly on the dielectric material or copper structure of the PCB 30.

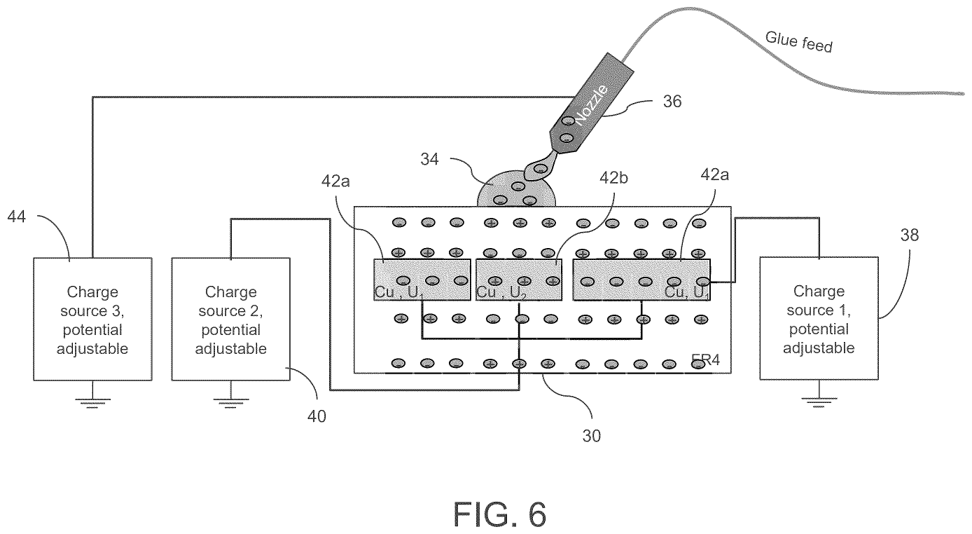

Referring to FIG. 6, the location of liquid or adhesive dispersal may be controlled by electrostatic fields. In the illustrated example, a first conductive structure 42a (e.g., a first copper layer) is embedded within or disposed below or disposed at one or more portions of the PCB 30 configured not to receive the adhesive 34 and a second conductive structure 42b (e.g., a second copper layer) is embedded within or disposed below or disposed at one or more portions of the PCB 30 configured to receive the adhesive 34. As shown, the first conductive structure 42a and/or the second conductive structure 42b may each respectively include one or more sections or portions disposed at or within the dielectric material remote from one another and electrically connected to one another. For example, the first conductive structure 42a includes two sections disposed remote from one another at the PCB 30 and the second conductive structure 42b includes one section disposed between the two sections of the first conductive structure 42a. The two sections of the first conductive structure 42a are electrically conductively connected to one another and electrically isolated from the second conductive structure 42b.

During application of the adhesive 34, the first conductive structure 42a is electrically connected to the first voltage source 38 and the second conductive structure 42b is electrically connected to the second voltage source 40, and the nozzle 36 dispensing the adhesive 34 is electrically connected to a third voltage source 44. The voltage of the first voltage source 38 and the third voltage source 44 may be negative to negatively charge the first conductive structure 42a and the nozzle 36, while the voltage of the second voltage source 40 may be positive to positively charge the second conductive structure 42b. Optionally, the first voltage source 38 and the third voltage source 44 may be positively charged to positively charge the first conductive structure 42a and the nozzle 36, while the voltage of the second voltage source 40 may be negative to negatively charge the second conductive structure 42b. Thus, the adhesive 34 and the first conductive structure 42a may be similarly charged to repel the adhesive 34 away from the portions of the PCB 30 corresponding to the first conductive structure 42a. The adhesive 34 and the second conductive structure 42b may be differently charged to attract the adhesive 34 to the portions of the PCB 30 corresponding to the second conductive structure 42b. Thus, with the adhesive 34 disposed on the non-conductive dielectric material of the PCB 30, polarization may be possible.

Optionally, the voltage levels applied to the first conductive structure 42a, the second conductive structure 42b and the nozzle 36 may be adjusted to accommodate different materials of the conductive structures and nozzle 36 and to provide enough force for attraction and repulsion of the adhesive 34. For example, the positive voltage sources may have a voltage of up to 1,000 volts or more and the negative voltage sources may have a voltage of −1,000 volts or lower.

Optionally, the electrically conductive structure of the imager PCB 30 that is electrically charged to be different from the electrical charge of the adhesive 34 (e.g., one is positively charged and one is negatively charged) may comprise a ring-shape or perimeter structure that circumscribes the imager of the imager PCB 30. Thus, the adhesive 34 may be attracted to the PCB surface at those areas to adhere or bond the lens holder 22 at the surface of the imager PCB 30 with the lens holder 22 at least partially circumscribing the imager of the imager PCB 30. Optionally, an inner ring or electrically charged structure may be established radially inward of the ring-shape or perimeter structure and may be electrically charged to correspond to the electrical charge of the adhesive 34 to repel the adhesive 34 and/or limit attraction and adhesion of the adhesive 34 immediately at or adjacent to the imager.

In the illustrated example of FIG. 2, the imager PCB and lens holder may be part of a camera (such as an exterior-mounted camera) where a rear housing may be mated with the lens holder after the imager printed circuit board is attached to the lens holder, such as by utilizing aspects of the windshield-mounted camera assemblies described in U.S. Pat. No. 10,272,857 and/or 10,264,219, which are hereby incorporated herein by reference in their entireties. The camera assembly includes an electrical connector portion that is configured to electrically connect to a vehicle cable or wire harness when the camera is installed at a vehicle. Optionally, the imager assembly may be part of a camera (such as an interior-mounted camera, such as a windshield-mounted forward-viewing camera) where the imager assembly may be disposed at a housing portion and the flexible connector may be electrically connected to another circuit board of the camera (such as a processor circuit board having an image processor and other circuitry disposed thereat), such as by utilizing aspects of the windshield-mounted camera assemblies described in U.S. Pat. Nos. 12,174,448; 11,635,672; 9,896,039; 9,871,971 and/or 9,596,387, which are all hereby incorporated herein by reference in their entireties. In such an application, the other circuit board may have the electrical connector at one side that is aligned with the connector portion of the rear housing for electrically connecting the camera to a vehicle cable (such as a coaxial cable) or wire harness.

The camera or sensor may comprise any suitable camera or sensor. Optionally, the camera may comprise a “smart camera” that includes the imaging sensor array and associated circuitry and image processing circuitry and electrical connectors and the like as part of a camera module, such as by utilizing aspects of the vision systems described in U.S. Pat. No. 10,099,614 and/or 10,071,687, which are hereby incorporated herein by reference in their entireties.

The system includes an image processor operable to process image data captured by the camera or cameras, such as for detecting objects or other vehicles or pedestrians or the like in the field of view of one or more of the cameras. For example, the image processor may comprise an image processing chip selected from the EYEQ family of image processing chips available from Mobileye Vision Technologies Ltd. of Jerusalem, Israel, and may include object detection software (such as the types described in U.S. Pat. Nos. 7,855,755; 7,720,580 and/or 7,038,577, which are hereby incorporated herein by reference in their entireties), and may analyze image data to detect vehicles and/or other objects. Responsive to such image processing, and when an object or other vehicle is detected, the system may generate an alert to the driver of the vehicle and/or may generate an overlay at the displayed image to highlight or enhance display of the detected object or vehicle, in order to enhance the driver's awareness of the detected object or vehicle or hazardous condition during a driving maneuver of the equipped vehicle.

The imaging sensor of the camera may capture image data for image processing and may comprise, for example, a two dimensional array of a plurality of photosensor elements arranged in at least 640 columns and 480 rows (at least a 640×480 imaging array, such as a megapixel imaging array or the like), with a lens focusing images onto the imaging array. The photosensor array may comprise a plurality of photosensor elements arranged in a photosensor array having rows and columns. The imaging array may comprise a CMOS imaging array having at least 300,000 photosensor elements or pixels, preferably at least 500,000 photosensor elements or pixels and more preferably at least one million photosensor elements or at least two million photosensor elements or pixels or at least three million photosensor elements or pixels or at least five million photosensor elements or pixels arranged in rows and columns. The imaging array may be sensitive to near-infrared light. The imaging array may capture color image data, such as via spectral filtering at the array, such as via an RGB (red, green and blue) filter or via a red / red complement filter or such as via an RCC (red, clear, clear) filter or the like. The logic and control circuit of the imaging sensor may function in any known manner, and the image processing and algorithmic processing may comprise any suitable means for processing the images and/or image data.

For example, the vision system and/or processing and/or camera and/or circuitry may utilize aspects described in U.S. Pat. Nos. 9,233,641; 9,146,898; 9,174,574; 9,090,234; 9,077,098; 8,818,042; 8,886,401; 9,077,962; 9,068,390; 9,140,789; 9,092,986; 9,205,776; 8,917,169; 8,694,224; 7,005,974; 5,760,962; 5,877,897; 5,796,094; 5,949,331; 6,222,447; 6,302,545; 6,396,397; 6,498,620; 6,523,964; 6,611,202; 6,201,642; 6,690,268; 6,717,610; 6,757,109; 6,802,617; 6,806,452; 6,822,563; 6,891,563; 6,946,978; 7,859,565; 5,550,677; 5,670,935; 6,636,258; 7,145,519; 7,161,616; 7,230,640; 7,248,283; 7,295,229; 7,301,466; 7,592,928; 7,881,496; 7,720,580; 7,038,577; 6,882,287; 5,929,786 and/or 5,786,772, and/or U.S. Publication Nos. US- 2014-0340510; US- 2014-0313339; US- 2014-0347486; US-2014-0320658; US-2014-0336876; US-2014-0307095; US-2014-0327774; US-2014-0327772; US-2014-0320636; US-2014-0293057; US-2014-0309884; US-2014-0226012; US-2014-0293042; US-2014-0218535; US-2014-0218535; US-2014-0247354; US-2014-0247355; US-2014-0247352; US-2014-0232869; US-2014-0211009; US-2014-0160276; US-2014-0168437; US-2014-0168415; US-2014-0160291; US-2014-0152825; US-2014-0139676; US-2014-0138140; US-2014-0104426; US-2014-0098229; US-2014-0085472; US-2014-0067206; US-2014-0049646; US-2014-0052340; US-2014-0025240; US-2014-0028852; US-2014-005907; US-2013-0314503; US-2013-0298866; US-2013-0222593; US-2013-0300869; US-2013-0278769; US-2013-0258077; US-2013-0258077; US-2013-0242099; US-2013-0215271; US-2013-0141578 and/or US-2013-0002873, which are all hereby incorporated herein by reference in their entireties. The system may communicate with other communication systems via any suitable means, such as by utilizing aspects of the systems described in U.S. Pat. Nos. 10,071,687; 9,900,490; 9,126,525 and/or 9,036,026, which are hereby incorporated herein by reference in their entireties.

Optionally, the camera may comprise a forward viewing camera, such as disposed at a windshield electronics module (WEM) or the like. The forward viewing camera may utilize aspects of the systems described in U.S. Pat. Nos. 12,174,448; 11,635,672; 11,124,130; 9,896,039; 9,871,971; 9,596,387; 9,487,159; 8,256,821; 7,480,149; 6,824,281 and/or 6,690,268, which are all hereby incorporated herein by reference in their entireties.

The camera assembly or module may utilize aspects of the cameras and connectors described in U.S. Pat. Nos. 11,801,795; 11,750,905; 11,711,598; 10,272,857; 10,250,004; 10,230,875; 10,142,532; 9,621,769; 9,277,104; 9,077,098; 8,994,878; 8,542,451 and/or 7,965,336, and/or U.S. Publication Nos. US-2009-0244361; US-2013-0242099; US-2014-0373345; US-2015-0124098; US-2015-0222795; US-2015-0327398; US-2016-0243987; US-2016-0268716; US-2016-0286103; US-2016-0037028; US-2017-0129419; US-2017-0133811; US-2017-0201661; US-2017-0280034; US-2017-0295306 and/or US-2018-0098033, which are hereby incorporated herein by reference in their entireties.

Changes and modifications in the specifically described embodiments can be carried out without departing from the principles of the invention, which is intended to be limited only by the scope of the appended claims, as interpreted according to the principles of patent law including the doctrine of equivalents.

1. A vehicular camera assembly, the vehicular camera assembly comprising:
a lens barrel accommodating a lens;
a camera housing comprising a first housing portion and a second housing portion;
wherein the lens barrel is disposed at the first housing portion;
an imager printed circuit board (imager PCB) comprising a first side and a second side opposite the first side and separated from the first side by a thickness of the imager PCB, wherein an imager is disposed at the first side of the imager PCB;
wherein the imager PCB is disposed at the camera housing with the imager facing the lens;
wherein an adhesive is disposed between and engages the first side of the imager PCB and the first housing portion to adhesively attach the imager PCB at the camera housing;
wherein, during assembly of the vehicular camera assembly, a nozzle dispenses the adhesive onto an attaching portion of the first side of the imager PCB and, with the adhesive dispensed onto the attaching portion of the first side of the imager PCB, the first housing portion is moved into engagement with the adhesive at the first side of the imager PCB;
wherein, as the nozzle dispenses the adhesive onto the attaching portion of the first side of the imager PCB, (i) the attaching portion of the first side of the imager PCB is electrically charged and (ii) the nozzle is electrically charged to electrically charge the adhesive; and
wherein, as the nozzle dispenses the adhesive onto the attaching portion of the first side of the imager PCB, one selected from the group consisting of (i) the attaching portion of the first side of the imager PCB is negatively charged and the adhesive is positively charged and (ii) the attaching portion of the first side of the imager PCB is positively charged and the adhesive is negatively charged.

2. The vehicular camera assembly of claim 1, wherein, as the nozzle dispenses the adhesive onto the attaching portion of the first side of the imager PCB, the attaching portion of the first side of the imager PCB is negatively charged and the adhesive is positively charged.

3. The vehicular camera assembly of claim 1, wherein, as the nozzle dispenses the adhesive onto the attaching portion of the first side of the imager PCB, the attaching portion of the first side of the imager PCB is positively charged and the adhesive is negatively charged.

4. The vehicular camera assembly of claim 1, wherein, as the nozzle dispenses the adhesive onto the attaching portion of the first side of the imager PCB, electrical current flows between the attaching portion of the first side of the imager PCB and the nozzle via the adhesive.

5. The vehicular camera assembly of claim 1, wherein, as the nozzle dispenses the adhesive onto the attaching portion of the first side of the imager PCB, (i) the imager PCB is electrically connected to a first voltage source to electrically charge the attaching portion of the first side of the imager PCB and (ii) the nozzle is electrically connected to a second voltage source to electrically charge the nozzle and the adhesive.

6. The vehicular camera assembly of claim 5, wherein the imager PCB comprises a dielectric portion and a conductive portion, and wherein the first voltage source electrically connects to the conductive portion of the imager PCB.

7. The vehicular camera assembly of claim 6, wherein the attaching portion of the first side of the imager PCB comprises the conductive portion.

8. The vehicular camera assembly of claim 6, wherein the conductive portion is embedded within the dielectric portion and spaced from the attaching portion of the first side of the imager PCB by the dielectric portion.

9. The vehicular camera assembly of claim 5, wherein the imager PCB comprises (i) a first conductive portion that corresponds to the attaching portion of the first side of the imager PCB that receives the adhesive and (ii) a second conductive portion that corresponds to a non-attaching portion of the first side of the imager PCB configured not to receive the adhesive, and wherein, as the nozzle dispenses the adhesive onto the attaching portion of the first side of the imager PCB, (a) the first conductive portion is electrically connected to the first voltage source to electrically charge the attaching portion of the first side of the imager PCB and (b) the second conductive portion is electrically connected to a third voltage source to electrically charge the non-attaching portion of the first side of the imager PCB, and wherein the attaching portion is oppositely charged from the adhesive and the non-attaching portion so that the adhesive is attracted to the attaching portion of the first side of the imager PCB and repelled from the non-attaching portion of the first side of the imager PCB.

10. The vehicular camera assembly of claim 1, wherein, as the first housing portion is moved into engagement with the adhesive, the first housing portion is electrically charged opposite from the adhesive.

11. The vehicular camera assembly of claim 1, wherein during assembly of the vehicular camera assembly, and with the first housing portion engaged with the adhesive at the first side of the imager PCB, the first housing portion is adjusted relative to the imager PCB to align the lens relative to the imager, and wherein, with the lens aligned relative to the imager, the adhesive is cured to secure the first housing portion relative to the imager PCB.

12. The vehicular camera assembly of claim 1, wherein the imager PCB comprises (i) a first portion that corresponds to the attaching portion of the first side of the imager PCB that receives the adhesive and (ii) a second portion that corresponds to a non-attaching portion of the first side of the imager PCB configured not to receive the adhesive, and wherein, as the nozzle dispenses the adhesive onto the attaching portion of the first side of the imager PCB, the first portion and the second portion of the imager PCB are electrically charged and a light source is electrically operated to illuminate the second portion of the imager PCB to electrically discharge the non-attaching portion of the first side of the imager PCB.

13. The vehicular camera assembly of claim 1, wherein the attaching portion of the imager PCB is electrically charged via one selected from the group consisting of (i) triboelectric techniques and (ii) static electric induction techniques.

14. A method for manufacturing a vehicular camera assembly, the method comprising:
providing an imager printed circuit board (imager PCB) comprising a first side and a second side opposite the first side and separated from the first side by a thickness of the imager PCB, wherein an imager is disposed at the first side of the imager PCB;
providing a camera housing comprising a first housing portion and a second housing portion, wherein a lens barrel accommodating a lens is disposed at the first housing portion;
dispensing an adhesive onto an attaching portion of the first side of the imager PCB via a nozzle;
as the nozzle dispenses the adhesive onto the attaching portion of the first side of the imager PCB, (i) electrically charging the attaching portion of the first side of the imager PCB and (ii) electrically charging the nozzle to electrically charge the adhesive;
wherein, as the nozzle dispenses the adhesive onto the attaching portion of the first side of the imager PCB, one selected from the group consisting of (i) the attaching portion of the first side of the imager PCB is negatively charged and the adhesive is positively charged and (ii) the attaching portion of the first side of the imager PCB is positively charged and the adhesive is negatively charged; and
with the adhesive dispensed onto the attaching portion of the first side of the imager PCB, moving the first housing portion into engagement with the adhesive at the first side of the imager PCB so that the imager at the imager PCB faces the lens; and
with the first housing portion engaged with the adhesive at the first side of the imager PCB, adjusting the first housing portion relative to the imager PCB to align the lens relative to the imager, and wherein, with the lens aligned relative to the imager, the adhesive is cured to secure the first housing portion relative to the imager PCB.

15. The method of claim 14, wherein electrically charging the attaching portion of the first side of the imager PCB comprises electrically connecting the imager PCB to a first voltage source, and wherein electrically charging the nozzle comprises electrically connecting the nozzle to a second voltage source.

16. The method of claim 15, wherein the imager PCB comprises a dielectric portion and a conductive portion, and wherein the first voltage source electrically connects to the conductive portion of the imager PCB, and wherein the conductive portion is embedded within the dielectric portion and spaced from the attaching portion of the first side of the imager PCB by the dielectric portion.

17. The method of claim 15, wherein the imager PCB comprises (i) a first conductive portion that corresponds to the attaching portion of the first side of the imager PCB that receives the adhesive and (ii) a second conductive portion that corresponds to a non-attaching portion of the first side of the imager PCB configured not to receive the adhesive, and wherein electrically charging the attaching portion of the first side of the imager PCB comprises (a) electrically connecting the first conductive portion to the first voltage source to electrically charge the attaching portion of the first side of the imager PCB and (b) electrically connecting the second conductive portion to a third voltage source to electrically charge the non-attaching portion of the first side of the imager PCB, and wherein the attaching portion is oppositely charged from the adhesive and the non-attaching portion so that the adhesive is attracted to the attaching portion of the first side of the imager PCB and repelled from the non-attaching portion of the first side of the imager PCB.

18. The method of claim 14, wherein moving the first housing portion into engagement with the adhesive comprises electrically charging the first housing portion so that the first housing portion is electrically charged opposite from the adhesive.

19. The method of claim 14, wherein the imager PCB comprises (i) a first portion that corresponds to the attaching portion of the first side of the imager PCB that receives the adhesive and (ii) a second portion that corresponds to a non-attaching portion of the first side of the imager PCB configured not to receive the adhesive, and wherein the method further comprises, as the nozzle dispenses the adhesive onto the attaching portion of the first side of the imager PCB, and as the first portion and the second portion of the imager PCB are electrically charged, operating a light source to illuminate the second portion of the imager PCB to electrically discharge the non-attaching portion of the first side of the imager PCB.

20. The method of claim 14, wherein electrically charging the attaching portion of the imager PCB comprises one selected from the group consisting of (i) triboelectric techniques and (ii) static electric induction techniques.
